(19) United States
(12) Patent Application Publication
(10) Pub. No.: US 2010/0155691 A1
(43) Pub. Date: Jun. 24, 2010

(54) METHOD OF FABRICATING SEMICONDUCTOR OXIDE NANOFIBERS FOR SENSOR AND GAS SENSOR USING THE SAME

(75) Inventors: Su Jae LEE, Daejeon (KR); Jin Ah Park, Gyeongsangnam-do (KR); Jaehyun Moon, Daejeon (KR); Tae Hyoung Zyung, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/536,664

(22) Filed: Aug. 6, 2009

(30) Foreign Application Priority Data
Dec. 19, 2008 (KR) 10-2008-0130398

(51) Int. Cl. H01L 29/66; H01L 21/36

(52) U.S. Cl. 257/9; 438/104; 438/49; 257/43; 977/762; 977/957; 257/E21.461; 257/E29.168

(57) ABSTRACT

A gas sensor for detecting environmentally harmful gases is provided. The sensor includes an insulating substrate, a metal electrode formed on the insulating substrate, and a sensing layer formed on the metal electrode and including a semiconductor oxide (Laₙ₊₁NiₙO₃ₙ₊₁(n=1,2,3)) nanofiber. Therefore, a semiconductor oxide (Laₙ₊₁NiₙO₃ₙ₊₁(n=1,2,3)) has an ABO₃-type basic crystalline structure and thus is stable in structure, and is a representative material having a nonstoichiometric composition due to oxygen defects. Since the semiconductor oxide has great oxygen defects on its surface, a great change in electrical resistance may be exhibited due to reactive gas adsorption and oxidation/reduction reaction on the oxide surface. Also, a method of fabricating the gas sensor is provided.

### CROSS-REFERENCE TO RELATED APPLICATION

This application claims priority to and the benefit of Korean Patent Application No. 10-2008-0130398, filed Dec. 19, 2008, the disclosure of which is incorporated herein by reference in its entirety.

### BACKGROUND

1. Field of the Invention

The present invention relates to a gas sensor using semiconductor oxide nanofibers and a method of fabricating the same.

2. Discussion of Related Art

Recently, interest in sensing noxious gases has been growing due to increased interest in environmental pollution and health. Gas sensors—originally developed to meet demands for sensing toxic and explosive gases—are now being developed to meet demands for enhancing quality of life in fields such as health management, environment monitoring, industrial health and safety, electric home appliances and home automation, food and agriculture, fabricating processes, national defense and terrorism. Therefore, since the gas sensors may become a means by which a future society free of disasters can be implemented, more accurate measurement and control of environmentally harmful gases are required. Further, new services including a ubiquitous sensor system and an environmental monitoring system are appearing.

To commercialize the gas sensors, the following requirements should be met. First, sensitivity should be high and detection of gas at low concentrations should be feasible. Second, specific gases should be selectively sensed, and the sensor should not be affected by coexistent gases. Third, the sensor should have stability that is not affected by an atmosphere including temperature, humidity, etc., and should have stable sensitivity that does not to deteriorate over time. Fourth, the sensor should have fast response to a gas in a repetitive manner. Fifth, the sensor is required to have multi-functions and low power consumption. In order to meet such requirements, various new sensor materials and gas sensors have been developed.

Among the gas sensors, gas sensors using ceramic include a semiconductor gas sensor, a solid electrolytic gas sensor, and a contact combustion-type gas sensor, and each of them is characterized by shape, structure and material. In particular, a gas sensor whose electrical resistivity is changed by gas adsorption and an oxidation/reduction reaction occurring on a surface of the metal oxide when ceramic semiconductor oxide such as zinc oxide (ZnO), tin oxide (SnO₂), tungsten oxide (WO₃), titanium oxide (TiO₂), or indium oxide (In₂O₃) is in contact with an environmental gas including H₂, CO, O₂, CO₂, NOx, a noxious gas, a volatile organic gas, ammonia, humidity, etc. is being progressively researched, and the characteristics have been partially utilized for a commercialized gas sensor.

Currently, research into development of a gas sensor using characteristics of a bulk material and new physical properties of a nanostructure including oxide nano thin films, nanoparticles, nanowires, nanofibers, nanotubes, nanoporousness, nanobelts, etc. has been actively under way. The small size of the nanostructure material, and an extremely great surface-to-volume ratio enable a sensor of fast response and ultra sensitivity to be fabricated. The new material enables the development of a gas sensor of fast response, high sensitivity, high selectivity, and low power consumption.

The metal semiconductor oxides such as ZnO, SnO₂, WO₃, TiO₂, and In₂O₃ have been known as representative materials for development of a gas sensor, and the gas sensors using such materials can exhibit considerably high sensitivity. However, it may be difficult to develop a sensor of high selectivity, long-term stability and reproducibility due to instable contact resistance and instability to an external environment.

### SUMMARY OF THE INVENTION

The present invention is directed to a gas sensor using semiconductor oxide nanofibers for implementing a commercialized gas sensor for detecting environmentally harmful gases characterized by ultra sensitivity, fast response, high selectivity and long-term stability and a method of fabricating the same.

One aspect of the present invention provides a method of fabricating an semiconductor oxide nanofiber for a gas sensor for detecting environmentally harmful gases, the method including: preparing an semiconductor oxide/polymer composite solution; coating the semiconductor oxide/polymer composite solution on a substrate; and annealing the substrate on which the semiconductor oxide/polymer composite solution is coated to form an semiconductor oxide (Laₙ₊₁NiₙO₃ₙ₊₁(n=1,2,3)) nanofiber.

The preparing of the semiconductor oxide/polymer composite solution may include: measuring a metal oxide precursor, a polymer and a solvent in a predetermined weight or volume ratio and mixing the results; and stirring the results at room temperature or higher to prepare the semiconductor oxide/polymer composite solution.

The semiconductor oxide/polymer composite solution may be coated on the insulating substrate by electrospinning.

The semiconductor oxide (Laₙ₊₁NiₙO₃ₙ₊₁(n=1,2,3)) may include LaNiO_{3+δ}, La₂NiO_{4+δ}, La₃Ni₂O_{7-δ}, or La₄Ni₃O_{10-δ}.

Another aspect of the present invention provides a gas sensor for detecting environmentally harmful gases, the sensor including: an insulating substrate; a metal electrode formed on the insulating substrate; and a sensing layer formed on the metal electrode and including a semiconductor oxide (Laₙ₊₁NiₙO₃ₙ₊₁(n=1,2,3)) nanofiber.

The substrate may be a single crystal substrate formed of Al₂O₃, MgO or SrTiO₃, a ceramic substrate formed of Al₂O₃ or quartz, a silicon substrate on which an insulating layer is coated or a glass substrate.

The metal electrode may include platinum (Pt), nickel (Ni), tungsten (W), titanium (Ti) or chrome (Cr).

The semiconductor oxide nanofiber may be formed to a diameter of 1 nm to 100 nm.

The gas senor may further include a micro thin film heater formed on the same plane as the metal electrode or on a rear surface of the metal electrode.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a perspective view of a nanofiber according to the present invention;

FIG. 2 is a flowchart illustrating a process of fabricating the nanofiber of FIG. 1;

FIG. 3 shows a scanning electron microscope (SEM) image of a surface of the semiconductor oxide nanofiber of FIG. 1 according to an exemplary embodiment of the present invention;

FIG. 4 is a result of an energy dispersive X-ray spectroscopy (EDS) of the semiconductor oxide nanofiber of FIG. 3;

FIG. 5 illustrates the configuration of a sensor using an semiconductor oxide (LNO) nanofiber according to the present invention;

FIG. 6 illustrates a change in electrical resistance according to a NO₂ gas reaction of the sensor illustrated in FIG. 5; and

FIG. 7 is a graph illustrating a change in sensitivity according to a change in the concentration of NO₂ gas in the sensor illustrated in FIG. 5.

### DETAILED DESCRIPTION OF EMBODIMENTS

The present invention will be described more fully hereinafter with reference to the accompanying drawings, in which exemplary embodiments of the invention are shown. This invention may, however, be embodied in different forms and should not be construed as limited to the embodiments set forth herein. In the drawings, portions irrelevant to a description of the present invention are omitted for clarity, and like reference numerals denote like elements.

Throughout the specification, it will be understood that when a portion “includes” an element, it is not intended to exclude other elements but can further include other elements.

A semiconductor oxide nanofiber for a gas sensor for detecting environmentally harmful gases, a method of fabricating the same, and a highly sensitive gas sensor for detecting environmentally harmful gases including the semiconductor oxide nanofiber will be described below with reference to the accompanying drawings.

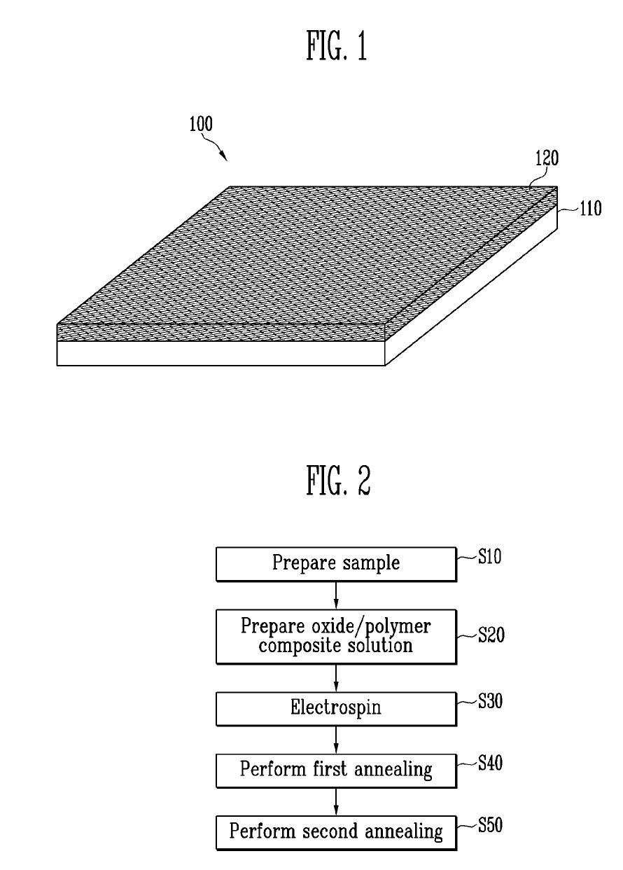

FIG. 1 is a perspective view of a nanofiber according to the present invention, and FIG. 2 is a flowchart illustrating a process of fabricating the nanofiber of FIG. 1.

Referring to FIG. 1, a semiconductor oxide nanofiber 120 according to the present invention is formed on an insulating substrate 110.

The insulating substrate 110 may be formed of a single crystal material such as Al₂O₃, MgO, SrTiO₃, etc., ceramic such as Al₂O₃ and quartz, silicon having an insulating layer formed thereon such as SiO₂/Si, or glass in order to maintain electrical insulating properties.

The semiconductor oxide nanofiber 120 includes a nanofiber having a Perovskite structure, i.e., a Ruddlesden-Popper-type (R-P) Laₙ₊₁NiₙO₃ₙ₊₁(n=1,2,3) nanofiber having an ABO₃-type structure as a basic structure.

The nanofiber 120 may be formed of LaNiO_{3+δ}, La₂NiO_{4+δ}, La₃Ni₂O_{7-δ}, or La₄Ni₃O_{10-δ}depending on compositions of materials. The semiconductor oxide nanofiber 120 may be formed on the insulating substrate 110 to form a layer thereon by electrospinning, and may be formed to a diameter of 1 nm to 100 nm.

A process of fabricating the nanofiber illustrated in FIG. 1 will be described with reference to FIG. 2.

First, a metal oxide precursor, a polymer and a solvent are prepared (S10).

Next, the prepared samples are mixed to fabricate an oxide/polymer composite solution (S20).

In the oxide/polymer composite solution, the metal oxide precursor, the high molecular polymer and the solvent are weighed in a predetermined weight or volume ratio to be mixed, and the obtained results are stirred at room temperature or higher for a long time period of several hours to several tens of hours to fabricate a composite solution for fabricating a beadless nanofiber.

The composite solution is electrospun on the insulating substrate 110 to form an oxide/polymer composite nanofiber (S30).

Afterwards, a first annealing process is performed on the composite nanofiber on the substrate 110 to volatilize the solvent. In order for the oxide/polymer composite nanofiber to have a composite nanofiber network having thermal and physical stability and solidity, and to have enhanced adhesion between the insulating substrate 110 and the composite nanofiber, the solvent may be completely removed through the annealing process performed at around glass transition temperature of the polymer (S40).

Then, a second annealing process is performed on the composite nanofiber from which the solvent is removed to form a polycrystalline semiconductor oxide nanofiber (S50). That is, the second annealing of the semiconductor oxide nanofiber may be performed at a temperature of 300° C. or higher for the sake of removal of the polymer and crystallization.

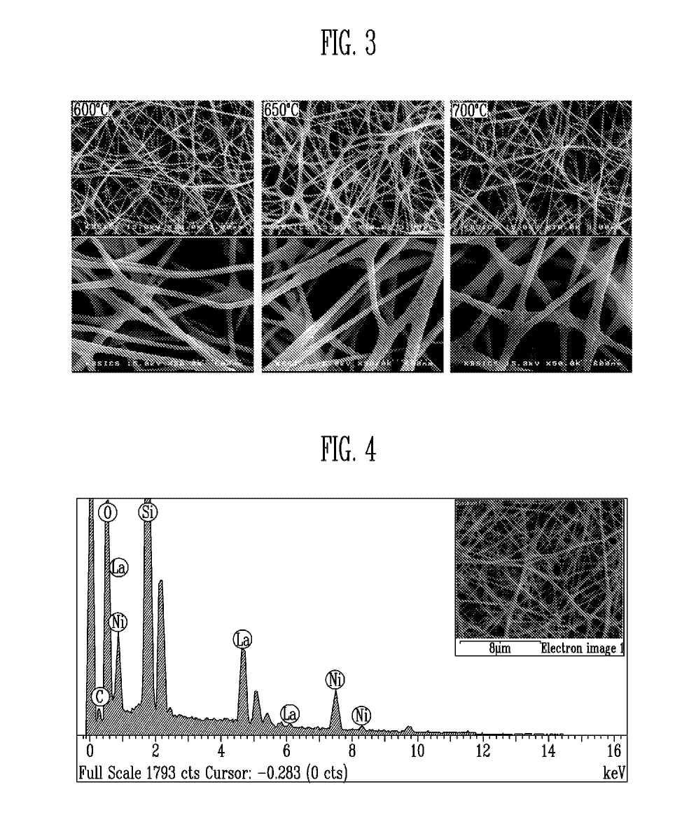

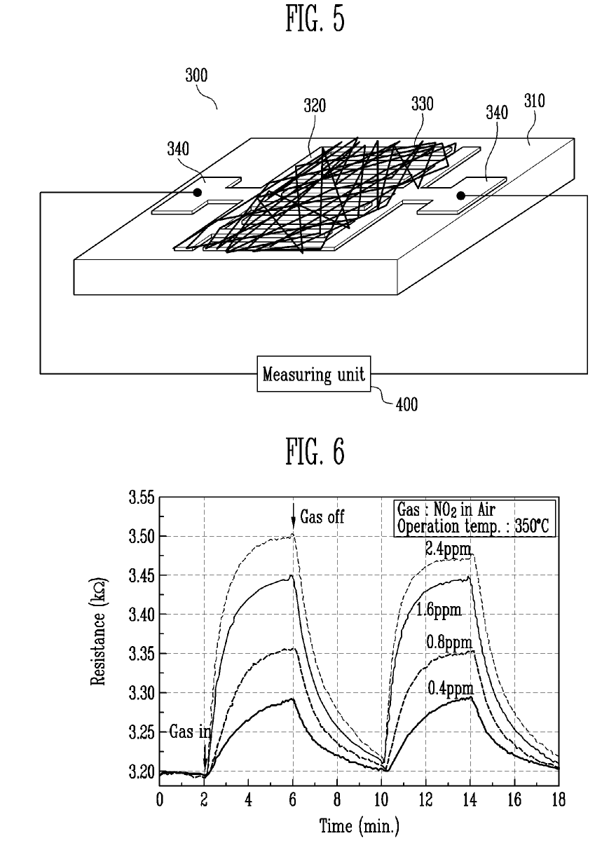

The exemplary embodiment of FIG. 1 will be described with reference to FIGS. 3 and 4.

FIG. 3 shows a scanning electron microscope (SEM) image of a surface of the semiconductor oxide nanofiber of FIG. 1 according to an exemplary embodiment of the present invention, and FIG. 4 is a result of an energy dispersive X-ray spectroscopy (EDS) of the semiconductor oxide nanofiber of FIG. 3.

FIGS. 3 and 4 illustrate the semiconductor oxide nanofiber of FIG. 1, which is formed by measuring and mixing a La₂NiO₄ (“LNO”) precursor, a poly4-vinyl phenol (PVP) polymer and ethyl alcohol at a predetermined weight ratio, and stirring the results at a temperature of 70° C. for 5 hours to 12 hours to fabricate a LNO/PVP polymer composite solution having a viscosity of 1200 cP. The LNO/PVP polymer composite solution is electrospun to form a LNO/PVP polymer composite nanofiber on a SiO₂/Si substrate. Also, the LNO/PVP polymer composite nanofiber is annealed at temperatures of 600° C., 650° C., and 700° C., respectively, to form an semiconductor oxide (LNO) nanofiber.

Referring to FIG. 3, the semiconductor oxide (LNO) nanofiber has a one-dimensional structure in which LNO nanograins are connected to each other, and it is observed that the size of the nanograin constituting the nanofiber increases in proportion to the annealing temperature.

Moreover, as illustrated in FIG. 4, in the semiconductor oxide (LNO) nanofiber annealed at a temperature of 650° C., only elements of La, Ni and O are found, and this means that a LNO nanofiber is formed.

Also, a semiconductor oxide (Laₙ₊₁NiₙO₃ₙ₊₁(n=1,2,3)) according to the present invention has a stable ABO₃-type basic crystalline structure, and is a representative material having a nonstoichiometric composition due to oxygen defects. Since the semiconductor oxide has great oxygen defects on its surface, a great change in electrical resistance is exhibited due to reactive gas adsorption and oxidation/reduction reaction on the oxide surface. Also, since the semiconductor oxide (Laₙ₊₁NiₙO₃ₙ₊₁(n=1,2,3)) nanofiber according to the present invention has an extremely great surface-to-volume ratio, it may be applied as a material of a gas sensor having ultra sensitivity, fast response and high selectivity.

A gas sensor using a semiconductor oxide (LNO) nanofiber of the present invention will be described with reference to FIGS. 5 to 7.

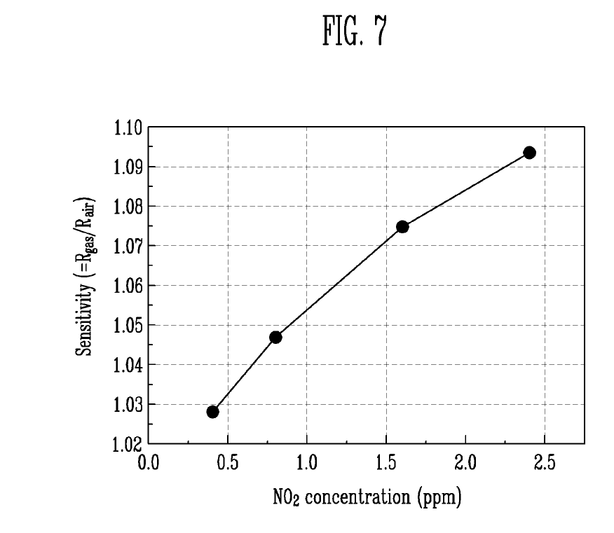

FIG. 5 illustrates the configuration of a gas sensor using a semiconductor oxide (LNO) nanofiber according to the present invention, FIG. 6 illustrates a change in electrical resistance according to a NO₂ gas reaction of the sensor illustrated in FIG. 5, and FIG. 7 is a graph illustrating a change in sensitivity according to a change in the concentration of NO₂ gas in the sensor illustrated in FIG. 5.

Referring to FIG. 5, a gas sensor 300 for detecting environmentally harmful gases using a semiconductor oxide (LNO) nanofiber of the present invention includes an insulating substrate 310, a metal electrode 320 formed on the substrate, an electrode pad 340 connected to the electrode and a semiconductor oxide (LNO) nanofiber 330 formed on the metal electrode 320.

The insulating substrate 310 may be a single crystal oxide substrate (e.g., Al₂O₃, MgO, and SrTiO₃) formed to a thickness of 0.1 mm to 1 mm, a ceramic substrate (e.g., Al₂O₃ and quartz), a silicon semiconductor substrate (e.g., SiO₂/Si) or a glass substrate.

The metal electrode 320 may be an interdigital transducer, may be formed of platinum (Pt), nickel (Ni), tungsten (W), titanium (Ti) or chrome (Cr), and may be formed to a thickness of 10 nm to 1000 nm. The electrode pad 340 may be formed of the same material as the metal electrode 320, but is not limited thereto.

The semiconductor oxide nanofiber 330 may be formed of a Laₙ₊₁NiₙO₃₊₁(n=1,2,3)-based oxide including LaNiO_{3+δ}, La₂NiO_{4+δ}, La₃Ni₂O_{7-δ}, and La₄Ni₃O_{10-δ}.

Through the process illustrated in FIG. 2, the semiconductor oxide (LNO) nanofiber 330 may be electrospun to be formed on the metal electrode 320. As a result, the LNO nanofiber may have polycrystalline properties, its number of junctions of nanocrystalline particles may increase, and a surface-to-volume ratio may increase, leading to an increased sensitivity to a specific gas. The nanofiber 330 may be formed to a diameter of 1 nm to 100 nm, but is not limited thereto.

The sensor using the semiconductor oxide (LNO) nanofiber 330 senses an environmentally harmful gas using a change in electrical resistance of the LNO nanofiber 330 caused by the reaction of a surface of the LNO nanofiber 330 with NO₂ gas, which is an environmentally harmful gas.

Referring to FIG. 6, examining a change in resistance through a measuring unit 400 of FIG. 5, as a result of changing the concentration of NO₂ gas from 0.4 ppm to 2.4 ppm at a temperature of 350° C. over time, it is observed that the resistance change increases in proportion to the concentration.

Moreover, FIG. 7 illustrates sensitivity according to gas concentration of a sensor 300, and the sensitivity of the gas sensor is defined as a ratio of resistance in a NO₂ gas atmosphere to that in the air. As illustrated in FIG. 7, the sensitivity of the sensor 300 of the present invention linearly increases according to the concentration of the NO₂ gas.

While the present invention is described in detail with reference to exemplary embodiments, the exemplary embodiments are employed to describe the present invention rather than limit the scope of the invention. For example, while a gas sensor having an interdigital transducer metal electrode structure using a semiconductor oxide (La₂NiO₄) nanofiber is described for example, the structure of the sensor is not limited in the present invention. Further, it is obvious that a structure in which a micro thin film heater is attached on the same plane as or on a rear surface of a metal electrode may be included. In addition, in the present invention, a Laₙ₊₁NiₙO₃ₙ₊₁(n=1,2,3)-based nanofiber may be applied to the gas sensor regardless of the structure of the gas sensor.

According to the present invention, a semiconductor oxide (Laₙ₊₁NiₙO₃ₙ₊₁(n=1,2,3)) has a stable ABO₃-type basic crystalline structure, and is a representative material having a nonstoichiometric composition due to oxygen defects. Since the oxide has great oxygen defects on its surface, a great change in electrical resistance may be exhibited due to reactive gas adsorption and oxidation/reduction reaction on the oxide surface.

Therefore, a gas sensor having ultra sensitivity, high selectivity, fast response and long-term stability can be implemented, and in particular, the gas sensor has long-term stability to the external environment. As a result, a new sensor material and a gas sensor applicable to a next generation system of a gas sensor for detecting environmentally harmful gases that requires more accurate measurement and control can be provided.

In the drawings and specification, there have been disclosed typical exemplary embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A method of fabricating a semiconductor oxide nanofiber for a gas sensor for detecting environmentally harmful gases, the method comprising:
preparing a semiconductor oxide/polymer composite solution;
coating the semiconductor oxide/polymer composite solution on a substrate; and
annealing the substrate on which the semiconductor oxide/polymer composite solution is coated to form a semiconductor oxide (Laₙ₊₁NiₙO₃ₙ₊₁(n=1,2,3)) nanofiber.

2. The method of claim 1, wherein the preparing of the semiconductor oxide/polymer composite solution comprises:
measuring a metal oxide precursor, a polymer and a solvent in a predetermined weight or volume ratio and mixing the results; and
stirring the results at room temperature or higher to prepare the semiconductor oxide/polymer composite solution.

3. The method of claim 2, wherein the semiconductor oxide/polymer composite solution is coated on the substrate by electrospinning.

4. The method of claim 2, wherein the semiconductor oxide (Laₙ₊₁NiₙO₃ₙ₊₁(n=1,2,3)) comprises LaNiO_{3+δ}, La₂NiO_{4+δ}, La₃Ni₂O_{7-δ}, or La₄Ni₃O_{10-δ}.

5. A gas sensor for detecting environmentally harmful gases, the sensor comprising:
an insulating substrate;
a metal electrode formed on the insulating substrate; and
a sensing layer formed on the metal electrode and including a semiconductor oxide (Laₙ₊₁NiₙO₃ₙ₊₁(n=1,2,3)) nanofiber.

6. The gas sensor of claim 5, wherein the substrate is a single crystal substrate formed of Al₂O₃, MgO or SrTiO₃, a ceramic substrate formed of Al₂O₃ or quartz, a silicon substrate on which an insulating layer is coated or a glass substrate.

7. The gas sensor of claim 5, wherein the metal electrode comprises platinum (Pt), nickel (Ni), tungsten (W), titanium (Ti) or chrome (Cr).

8. The gas sensor of claim 5, wherein the semiconductor oxide nanofiber is formed to a diameter of 1 nm to 100 nm.

9. The gas sensor of claim 7, further comprising a micro thin film heater formed on the same plane as the metal electrode or on a rear surface of the metal electrode.
